(19) United States
(12) Patent Application Publication
(10) Pub. No.: US 2026/0029435 A1
(43) Pub. Date: Jan. 29, 2026

(54) ELECTRONIC DEVICE INCLUDING AN ELECTRIC CURRENT SENSOR

(71) Applicant: STMicroelectronics International N.V., Geneva (CH)

(72) Inventors: Alberto URDANETA CALZADILLA, Grenoble (FR); Ludovic FOURNEAUD, Saint Vincent de Mercuze (FR)

(73) Assignee: STMicroelectronics International N.V., Geneva (CH)

(21) Appl. No.: 19/282,316

(22) Filed: Jul. 28, 2025

(30) Foreign Application Priority Data
Jul. 29, 2024 (FR) FR2408393

(51) Int. Cl. G01R 15/18; H05K 1/18

(52) U.S. Cl. CPC G01R 15/181; H05K 1/181; H05K 2201/10151

(57) ABSTRACT

An electronic device includes a support substrate and an electronic chip assembled to the support substrate. The support substrate includes an electric current sensor using a planar transformer. The planar transformer is configured to: sense a magnetic field generated by an electric current to be monitored, and output a voltage induced by this magnetic field in the planar transformer to the electronic chip.

### PRIORITY CLAIM

This application claims the priority benefit of French Application for Patent No. FR2408393, filed on Jul. 29, 2024, the content of which is hereby incorporated by reference in its entirety to the maximum extent allowable by law.

### TECHNICAL FIELD

Embodiments and implementations relate to electric current sensors.

Electric current sensors are devices used to measure an intensity of an electric current flowing in an electrically-conductive wire or in an electrically-conductive track.

### BACKGROUND

It is interesting to manufacture current sensors configured to monitor an electric current flowing on a printed circuit board.

It is possible to use a dedicated component, mounted on the printed circuit board, like a current sensor. This sensor is then configured to generate a current according to the intensity of the monitored current. Afterwards, this signal is transmitted to a processing component, for example a microcontroller. For example, it is possible to use a Rogowski coil as a current sensor in a dedicated component.

The use of such a current sensor requires having a printed circuit board that is large enough to integrate this current sensor. Furthermore, in some cases, the conductive tracks conveying the current to be monitored or the current conveying the signal originating from the sensor reflecting the measured current passes through the printed circuit board and could be exposed to external magnetic radiations which could reduce the performances of the electric current sensor.

Hence, there is a need to provide a solution allowing simplifying the use of an electric current sensor to monitor a current conveyed in a printed circuit board.

### SUMMARY

According to one aspect, an electronic device is provided comprising a support substrate and an electronic chip assembled to the support substrate, the support substrate including an electric current sensor comprising a planar transformer configured to: sense a magnetic field generated by an electric current to be monitored, and output a voltage induced by this magnetic field to said electronic chip.

Hence, such an electronic device integrates a current sensor configured to monitor an electric current. In particular, the current sensor is integrated into a support substrate supporting an electronic chip configured to process the signal generated by this current sensor. Such a current sensor has the advantage of avoiding the use of an electric current sensor formed in an independent electronic component. Hence, such an electronic device allows for reducing the cost of using a current sensor.

Furthermore, in such an electronic device, the current sensor is located proximate to the electronic chip processing the signal generated by the sensor. Thus, the signal generated by the current sensor travels a shorter distance to reach the electronic chip. This allows for reducing disturbances on this signal.

In an advantageous embodiment, the planar transformer includes at least one electrically-conductive winding. The transformer may comprise several electrically-conductive windings. In this case, the windings may extend in the same plane.

Advantageously, the support substrate includes an electrically-conductive track conveying the current to be monitored.

In an advantageous embodiment, the conductive track conveying the current to be monitored extends in the support substrate between the windings of the planar transformer.

Advantageously, the electric current sensor comprises at least one ferromagnetic element in the support substrate.

Said at least one ferromagnetic element allows for confining and concentrating the magnetic field B (referred to also as the magnetic flux density un units of tesla) generated by the current to be monitored. In this manner, the current induced in the windings of the sensor is higher.

Preferably, the electric current sensor comprises a ferromagnetic element between the planar transformer and the electronic chip.

This ferromagnetic element allows for limiting the electromagnetic interactions with the electronic chip of the electronic device. In particular, the ferromagnetic element allows for isolating the electronic chip from the magnetic field H (referred to also as the magnetic field strength in units of ampere per meter) generated by the current to be monitored in the conductive track.

In an advantageous embodiment, the electric current sensor also comprises a ferromagnetic element under the planar transformer.

Advantageously, the device further comprises an array of connecting elements under the support substrate, the array of connecting elements being configured to be assembled to a printed circuit board.

Preferably, the planar transformer is configured to be placed opposite a conductive track conveying the current to be monitored on the printed circuit board.

According to another aspect, a system is proposed comprising: a printed circuit board, and the electronic device as defined before, assembled to the printed circuit board.

Advantageously, the printed circuit board includes a track configured to convey an electric current, and said electronic device is configured to monitor this electric current.

According to another aspect, a method is provided for manufacturing an electronic device, comprising obtaining a support substrate and assembling an electronic chip to the support substrate, obtaining the support substrate including an electric current sensor comprising a planar transformer configured to: sense a magnetic field generated by an electric current to be monitored, and output a voltage induced by this magnetic field to said electronic chip.

In an advantageous implementation, the planar transformer includes at least one electrically-conductive winding.

Advantageously, the support substrate includes an electrically-conductive track conveying the current to be monitored.

In an advantageous embodiment, the conductive track conveying the current to be monitored extends in the support substrate between the windings of the planar transformer.

Advantageously, the electric current sensor comprises at least one ferromagnetic element in the support substrate.

Preferably, the electric current sensor comprises a ferromagnetic element between the planar transformer and the electronic chip.

In an advantageous implementation, the electric current sensor also comprises a ferromagnetic element under the planar transformer.

Advantageously, the method further comprises obtaining an array of connecting elements under the support substrate, the array of connecting elements being configured to be assembled to a printed circuit board.

Preferably, the planar transformer is configured to be placed opposite a conductive track conveying the current to be monitored on the printed circuit board.

According to another aspect, a method is provided for manufacturing an electronic device, comprising forming a support substrate and assembling an electronic chip to the support substrate, forming the support substrate including forming an electric current sensor comprising a planar transformer configured to: sense a magnetic field generated by an electric current to be monitored, and output a voltage induced by this magnetic field to said electronic chip.

In an advantageous implementation, forming the electric current sensor comprises forming at least one electrically-conductive winding.

Advantageously, forming the support substrate includes forming an electrically-conductive track conveying the current to be monitored.

In an advantageous implementation, the conductive track conveying the current to be monitored extends in the support substrate between the windings of the planar transformer.

Preferably, forming the electric current sensor comprises forming at least one ferromagnetic element in the support substrate.

Advantageously, forming the electric current sensor comprises forming a ferromagnetic element between the planar transformer and the electronic chip.

Preferably, forming the electric current sensor also comprises forming a ferromagnetic element under the planar transformer.

Advantageously, the method further comprises forming an array of connecting elements under the support substrate, the array of connecting elements being configured to be assembled to a printed circuit board.

In an advantageous implementation, the planar transformer is formed so as to be able to be placed opposite a conductive track conveying the current to be monitored on the printed circuit board.

### BRIEF DESCRIPTION OF THE DRAWINGS

Other advantages and features of the invention will become apparent upon reading the detailed description of non-limiting embodiments, and from the appended drawings wherein:

FIG. 1 illustrates a longitudinal sectional view of a system comprising an electronic device and a printed circuit board;

FIG. 2 illustrates a sectional view of the electric current sensor in FIG. 2;

FIGS. 3, 4, 5 and 6 show further longitudinal sectional view of system implementations;

FIG. 7 illustrates an implementation of a method for manufacturing an electronic device; and

FIGS. 8-15 show cross-sectional views of steps in the method.

### DETAILED DESCRIPTION

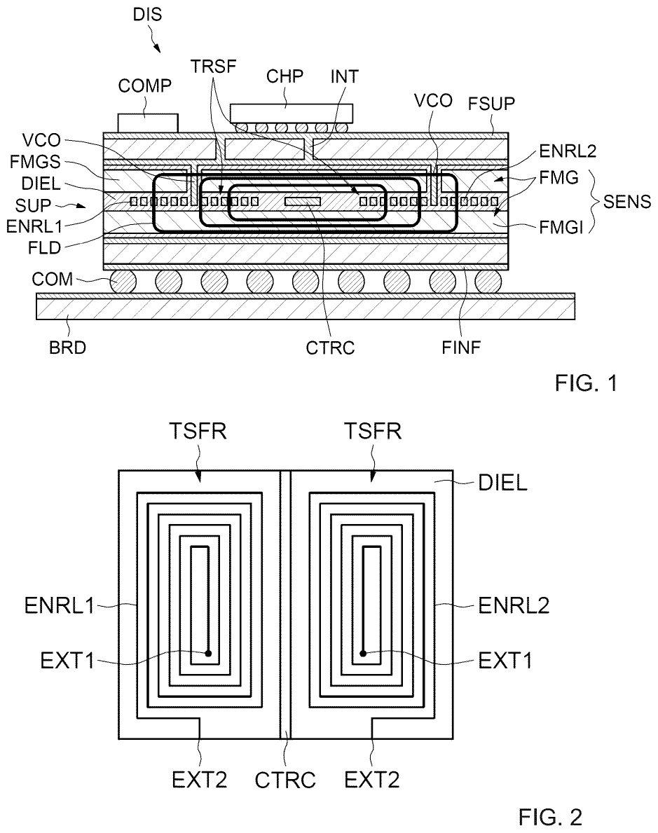

FIG. 1 illustrates a first embodiment of a longitudinal sectional view of a system comprising an electronic device DIS and a printed circuit board BRD (also referred to in the art as a printed circuit board (PCB)).

The electronic device DIS is configured to be connected to the printed circuit board BRD. The electronic device comprises an electric current sensor SENS, formed in a support substrate SUP, and an electronic chip CHP (also referred to an integrated circuit die). The electronic device DIS may comprise other electronic components COMP mounted at the surface (i.e., assembled to the support substrate SUP). For example, the electronic device DIS is a microcontroller.

The support substrate SUP is a laminated substrate which integrates the electronic current sensor SENS.

The support substrate SUP is in the form of a board having an upper main face FSUP, defining the top of the support substrate, and a lower main face FINF, defining the bottom of the support substrate SUP. The electronic chip CHP and the electronic components COMP are assembled at the upper main face FSUP of the support substrate.

The electronic device DIS also has an array of connecting elements COM assembled at the lower face of the support substrate SUP. This array of connecting elements COM is configured to be assembled to the printed circuit board BRD. The array of connecting elements then allows for electrically connecting the support substrate to the printed circuit board.

In this embodiment, the array of connecting elements COM is a ball grid array (BGA). Nevertheless, alternatively, it is possible to provide for an array of connecting elements COM of the land grid array type (LGA).

The electric current sensor SENS is configured to sense an electric current flowing in an electrically-conductive track CTRC. The electric current to be monitored is an alternating current. For example, the electric current to be monitored may be a current allowing controlling an electric motor (not shown). Other applications are possible. For example, it is possible to use such an electronic device DIS in 5G or LIDAR applications to monitor a current used to form an electromagnetic beam.

In the embodiment illustrated in FIG. 1, the electric current to be monitored flows in a conductive track CTRC integrated into the support substrate SUP. This current to be monitored may originate from a track (not shown) of the printed circuit board BRD and be transmitted to the track of the support substrate via the array of connecting elements.

When the electric current to be monitored flows in the conductive track CTRC, this electric current generates a magnetic field FLD. This magnetic field FLD induces an electric current in the electric current sensor SENS. The sensor is configured to emit a signal based on induced electric current. The current sensor is electrically connected to the electronic chip CHP via an interconnection circuit INT integrated into the support substrate SUP. In this manner, the signal emitted by the current sensor SENS could be transmitted to the electronic chip CHP for processing. For example, the electronic chip CHP may be configured to adapt the intensity of the current to be monitored according to the voltage induced in the current sensor SENS. For example, the electronic chip CHP may adapt the current to be monitored to adapt the control of an electric motor.

The current sensor SENS includes a planar transformer TRSF. In particular, the planar transformer TRSF comprises at least one electrically-conductive winding. In the embodiment illustrated in FIGS. 1 and 2, the planar transformer TRSF includes two electrically-conductive windings ENRL1, ENRL2. Each winding ENRL1, ENRL2 is formed by a conductive track or by a coiled conductive wire. The conductive track conveying the electric current to be monitored extends between the two windings.

The two windings ENRL1, ENRL2 are located in the same plane parallel to the main faces FSUP, FINF of the support substrate SUP. FIG. 2 illustrates a sectional view of the electric current sensor SENS according to this parallel plane.

The two windings ENRL1, ENRL2 are also spaced apart from one another by a distance comprised between 20 micrometers and 200 micrometers.

Each winding ENRL1, ENRL2 has a thickness comprised between 10 micrometers and 50 micrometers. Each winding ENRL1, ENRL2 has a width comprised between 50 micrometers and 10 millimeters.

Each winding ENRL1, ENRL2 has a first end EXT1 connected to an electrically-conductive via VCO allowing electrically connecting this winding to the electronic chip via the interconnection circuit INT. Each winding also has a second end EXT2 connected to the electronic chip CHP. The electronic chip CHP is then configured to observe a voltage difference between the two ends of each winding.

In this manner, the voltage induced at the output of each winding ENRL1, ENRL2 from the magnetic field produced by the track CTRC conveying the current to be monitored can be transmitted to the electronic chip CHP.

Each winding ENRL1, ENRL2 may be formed of a metallic material such as copper.

Each winding ENRL1, ENRL2 may have any shape. For example, it may be rectangular shaped as schematically illustrated in FIG. 2 or circular shaped.

For example, the length of each winding ENRL1, ENRL2 may be comprised between 200 micrometers and 50 millimeters, with a number of coils comprised between one and one hundred.

The windings ENRL1, ENRL2 are arranged in a dielectric material layer DIEL of the electric current sensor SENS. The dielectric material layer DIEL has a thickness comprised between 10 micrometers and 100 micrometers.

The electric current sensor SENS includes at least one ferromagnetic element FMG. Said at least one ferromagnetic element FMG allows for confining and concentrating the magnetic field B generated by the current to be monitored. In this manner, the current induced in the windings ENRL1, ENRL2 of the sensor SENS is higher.

In the embodiment illustrated in FIG. 1, the electric current sensor SENS includes two ferromagnetic elements FMGS, FMGI located on each side of the dielectric material layer.

In particular, the electric current sensor SENS includes an upper ferromagnetic element FMGS extending over the upper face of the dielectric layer DIEL of the current sensor SENS. This upper ferromagnetic element FMGS allows for limiting the ferromagnetic interactions with the electronic chip CHP of the electronic device DIS. In particular, the upper ferromagnetic element FMGS allows for isolating the electronic chip CHP from the magnetic field H generated by the current to be monitored flowing in the conductive track CTRC.

The upper ferromagnetic element FMGS has one opening for each conductive via connecting the windings to the interconnection circuit. Thus, each opening is crossed by a conductive via.

Each ferromagnetic element FMG has a thickness comprised between 10 micrometers and one millimeter.

For example, each ferromagnetic element FMG may be formed of a ferromagnetic resin or of a ferromagnetic film. This hardened resin may include a dielectric material such as a polymer, for example nylon 6, nylon 12, or a polyamide including a magnetic material for example a strontium (Sr) ferrite, a neodymium-iron-boron (NdFeB) alloy, a CoZrO alloy which has high-frequency performances suitable for radiofrequency applications, a cobalt-nickel-iron (CoNiFe) alloy, or amorphous iron-cobalt alloys, and any combination of at least some of the aforementioned elements.

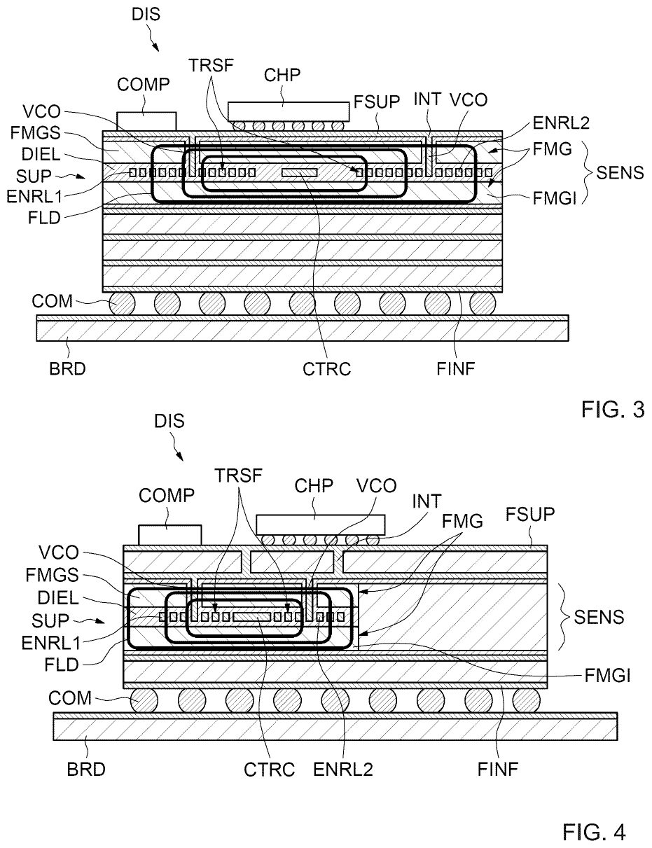

In the embodiment illustrated in FIG. 1, the electric current sensor SENS is located at mid-height in the thickness of the support substrate SUP. Nevertheless, it is possible to place the electric current sensor SENS at other heights in the thickness of the support substrate SUP. For example, it is possible to place the electric current sensor SENS at the top of the support substrate SUP, as illustrated in FIG. 3, or at the bottom of the support substrate SUP (not illustrated).

Moreover, the electric current sensor SENS may extend over the entirety of the width and of the length of the support substrate SUP. Nevertheless, it is possible to provide for an electric current sensor SENS extending partially over the width and the length of the support substrate, as illustrated in FIG. 4.

Such an electronic device DIS allows for avoiding the use of an electric current sensor formed in an independent electronic component. Hence, such an electronic device DIS allows for reducing the cost of using an electric current sensor.

Furthermore, in such an electronic device DIS the electric current sensor SENS is located proximate to the electronic chip CHP processing the signal transmitted by the electric current sensor SENS. Thus, the signal of the electric current sensor SENS travels a shorter distance to reach the electronic chip CHP. This allows for reducing disturbances on this signal.

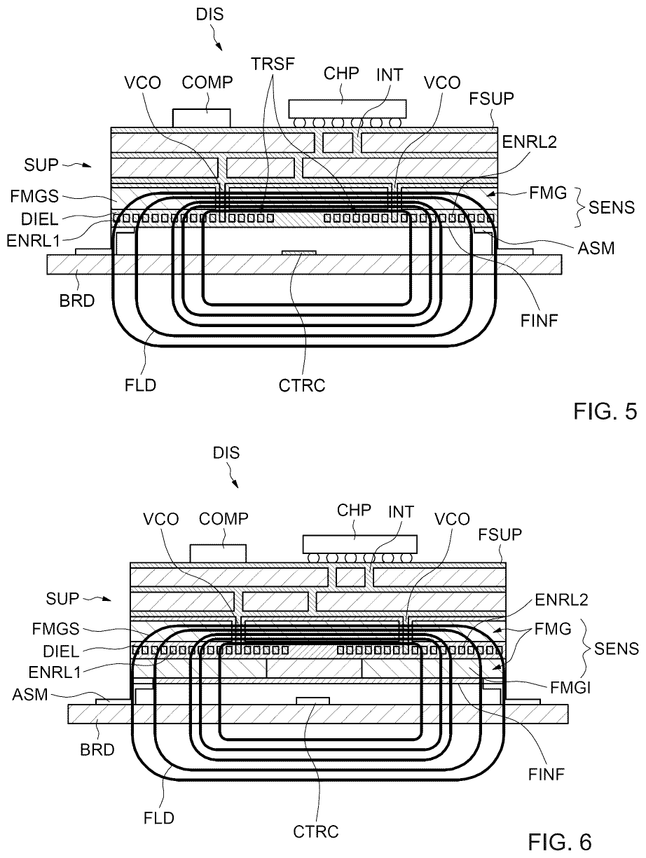

FIG. 5 illustrates another embodiment of an electronic device DIS. The electronic device DIS may be connected to the printed circuit board via an array of connecting elements COM of the land grid array type. Nevertheless, alternatively, it is possible to provide for an array of connecting elements COM of the ball grid array type.

In the illustrated embodiment, the conductive track CTRC, conveying the electric current to be monitored, is located outside the support substrate SUP of the electronic device DIS. In particular, the conductive track CTRC extends directly over the printed circuit board BRD.

In this embodiment, the electronic device DIS comprises assembly elements ASM configured to assemble the support substrate SUP to the printed circuit board BRD while clearing a space between the support substrate SUP and this printed circuit board BRD. In this manner, the electric current sensor SENS may be placed opposite the conductive track CTRC which extends in the space between the printed circuit board BRD and the support substrate SUP.

The electric current sensor SENS is then placed at the bottom of the support substrate SUP. Furthermore, the space between the support substrate SUP and the printed circuit board BRD is reduced enough to enable the magnetic field generated by the electric current to be monitored to reach the windings of the sensor SENS.

In the embodiment illustrated in FIG. 5, the electric current sensor SENS has one single ferromagnetic element FMGS located above the dielectric layer DIEL. The electric current sensor SENS has no ferromagnetic elements under the dielectric layer DIEL. The dielectric layer DIEL integrating the windings of the electric current sensor SENS is then located at the bottom of the support substrate SUP.

Alternatively, in the embodiment illustrated in FIG. 6, the electric current sensor SENS includes two ferromagnetic elements FMGS, FMGI on each side of the dielectric layer DIEL integrating the windings of the sensor SENS. The ferromagnetic element FMGI located under the dielectric layer is then placed at the bottom of the support substrate SUP and has an opening OPN opposite the conductive track CTRC conveying the electric current to be monitored. This opening OPN then enables the magnetic field FLD generated by the electric current to be monitored to reach the windings ENRL1, ENRL2 of the sensor SENS.

The embodiments illustrated in FIGS. 5 and 6 have the advantage of avoiding conveying the current to be monitored in a conductive track of the support substrate SUP. Thus, because of the distance between the electronic device DIS and the conductive track conveying the current to be monitored, the electronic device is subjected to less heat losses from the conductive track CTRC by Joule effect. In this manner, it is possible to monitor a higher rated current.

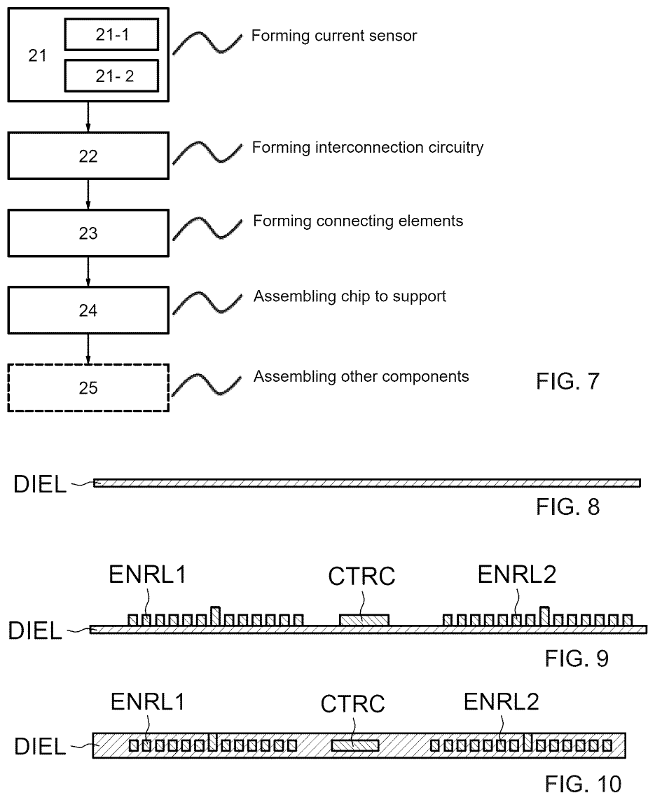

FIG. 7 illustrates an implementation of a method for manufacturing an electronic device DIS as described before.

The manufacturing method comprises forming 21 the electric current sensor SENS when forming the support substrate SUP.

Forming the electric current sensor SUP comprises in step 21 includes forming 21-1 a dielectric material layer DIEL and forming 21-2 windings ENRL1, ENRL2 of the electric current sensor SENS.

In particular, the method of step 21 comprises forming a first thickness of the dielectric material layer DIEL. The result of the formation of this first thickness of the dielectric material layer is illustrated in FIG. 8. Afterwards, the method of step 21 comprises depositing the windings ENRL1, ENRL2 of the electric current sensor SENS and possibly depositing a conductive track conveying the current to be monitored in the case of manufacture of an electronic device DIS as described with reference to FIGS. 1 to 4 wherein the conductive track extends in the support substrate SUP. The result of this deposition is illustrated in FIG. 9. Afterwards, the method of step 21 comprises depositing a second thickness of the dielectric material layer DIEL to form the dielectric material layer DIEL. The result of this deposition is illustrated in FIG. 10.

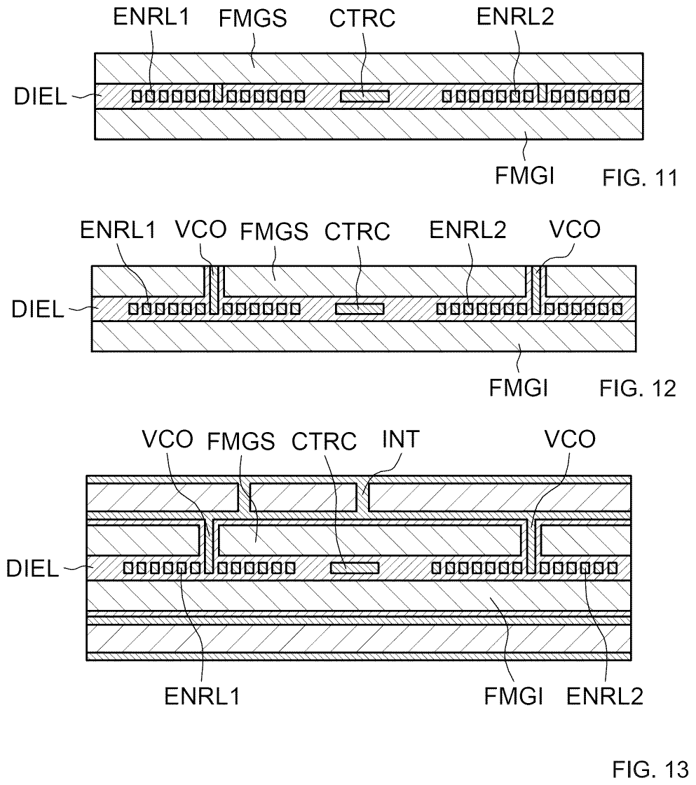

Afterwards, the method of step 21 further comprises depositing said at least one ferromagnetic element FMG over the dielectric material layer. In particular, the method comprises depositing only an upper ferromagnetic element, or depositing an upper ferromagnetic element and a lower ferromagnetic layer. For example, the deposition of a ferromagnetic element is carried out by depositing a ferromagnetic film or a ferromagnetic resin. FIG. 11 illustrates an example of the result of such a deposition of ferromagnetic elements FMGS, FMGI.

Afterwards, the method comprises forming 22 an interconnection circuit INT of the support substrate and conductive vias VCO allowing connecting the windings ENRL1, ENRL2 to the interconnection circuit. FIG. 12 illustrates an example of the result of formation of conductive vias. In order to form these conductive vias, openings are formed in the upper ferromagnetic element and then a dielectric material thickness is deposited in these openings. Afterwards, an opening is formed in each dielectric material thickness and then conductive vias are deposited in these openings. The result of the formation of the interconnection circuit is illustrated in FIG. 13.

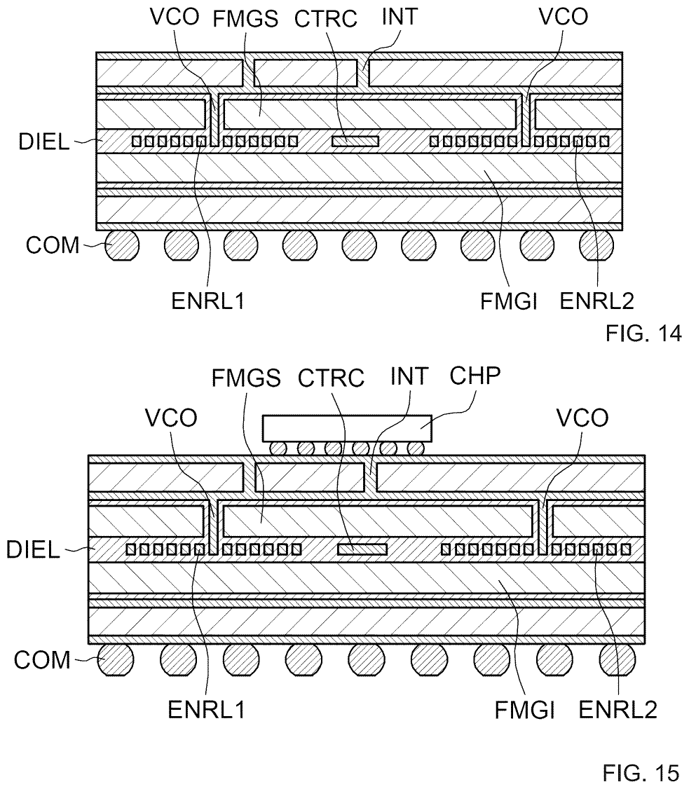

Afterwards, the method comprises forming 23 an array of connecting elements COM for the assembly of the electronic device DIS to a printed circuit board BRD. FIG. 14 illustrates an example of the result of formation of an array of connecting elements COM.

Afterwards, the method comprises assembling 24 an electronic chip CHP to the support substrate SUP so as to connect the electronic chip CHP to the interconnection circuit INT. FIG. 15 illustrates an example of the result of assembly of an electronic chip CHP on the support substrate SUP.

The method may also comprise assembling 25 other components COMP to the support substrate SUP.

Once manufactured, the electronic device can be assembled to a printed circuit board. In the case of an electronic device such as those illustrated in FIGS. 5 and 6, the printed circuit board has a conductive track conveying the current to be monitored. The electronic device is then placed over this conductive track.

Of course, the present invention is susceptible to various variants and modifications that would appear to a person skilled in the art. For example, the electric current sensor may be deprived of a dielectric material layer DIEL. Indeed, the conductivity is relatively low such that a dielectric material layer DIEL might be not necessary.

1. An electronic device, comprising:
a support substrate having an upper surface; and
an electronic chip assembled to the upper surface of the support substrate;
wherein the support substrate includes an electric current sensor comprising a planar transformer configured to:
sense a magnetic field generated by an electric current to be monitored; and
output a voltage induced by this magnetic field through an electrical connection to said electronic chip.

2. The device according to claim 1, wherein the planar transformer includes at least one electrically-conductive winding.

3. The device according to claim 1, wherein the support substrate includes an electrically-conductive track conveying the current to be monitored.

4. The device according to claim 1, wherein the electric current sensor comprises at least one ferromagnetic element in the support substrate.

5. The device according to claim 4, wherein the electric current sensor comprises a further ferromagnetic element between the planar transformer and the electronic chip.

6. The device according to claim 4, wherein the electric current sensor comprises a further ferromagnetic element with the planar transformer between the electronic chip and the further ferromagnetic element.

7. The device according to claim 1, further comprising an array of connecting elements at a lower surface of the support substrate opposite said upper surface, the array of connecting elements being configured to be assembled by electrical connection to a printed circuit board.

8. The device according to claim 7, wherein the support substrate includes an electrically-conductive track conveying the current to be monitored, and wherein the planar transformer is configured to be placed opposite a conductive track conveying the current to be monitored on the printed circuit board.

9. A system, comprising:
the electronic device according to claim 1; and
a printed circuit board including a track configured to convey an electric current;
wherein the electronic device is assembled to the printed circuit board and configured to monitor said electric current.

10. A method for manufacturing an electronic device, comprising:
obtaining a support substrate having an upper surface; and
assembling an electronic chip to the upper surface of the support substrate;
wherein the support substrate includes an electric current sensor comprising a planar transformer configured to:
sense a magnetic field generated by an electric current to be monitored, and
output a voltage induced by this magnetic field to said electronic chip.

11. The manufacturing method according to claim 10, wherein the electric current sensor comprises at least one electrically-conductive winding.

12. The method according to claim 10, wherein the support substrate includes an electrically-conductive track conveying the current to be monitored.

13. The method according to claim 10, wherein the electric current sensor comprises at least one ferromagnetic element in the support substrate.

14. The method according to claim 13, wherein the electric current sensor comprises a further ferromagnetic element between the planar transformer and the electronic chip.

15. The method according to claim 13, wherein the electric current sensor comprises a further ferromagnetic element with the planar transformer between the electronic chip and the further ferromagnetic element.

16. The method according to claim 10, further comprising obtaining an array of connecting elements at a lower surface of the support substrate opposite said upper surface, the array of connecting elements being configured to be assembled for electrical connection to a printed circuit board.

17. The method according to claim 16, wherein the support substrate includes an electrically-conductive track conveying the current to be monitored, and wherein the planar transformer is configured to be placed opposite a conductive track conveying the current to be monitored on the printed circuit board.
